(19) United States
(12) Patent Application Publication
(10) Pub. No.: US 2018/0254403 A1
(43) Pub. Date: Sep. 6, 2018

(54) INTERDIGITATED ELECTRODE PATTERNED MULTI-LAYERED PIEZOELECTRIC LAMINATE STRUCTURE

(71) Applicant: KOREA INSTITUTE OF CERAMIC ENGINEERING AND TECHNOLOGY, Jinju-si (KR)

(72) Inventors: Young Hun JEONG, Jinju-si (KR); Jeong Ho CHO, Suwon-si (KR); Jong Hoo PAIK, Anyang-si (KR); Min Seon LEE, Jinju-si (KR)

(21) Appl. No.: 15/895,530

(22) Filed: Feb. 13, 2018

(30) Foreign Application Priority Data
Mar. 3, 2017 (KR) 10-2017-0027504

(51) Int. Cl. H01L 41/047; H01L 41/083; H01L 41/273; H04R 17/00

(52) U.S. Cl. CPC H01L 41/0471; H04R 17/005; H01L 41/273; H01L 41/083

(57) ABSTRACT

An interdigitated electrode patterned multi-layered piezoelectric laminate structure is provided, which comprises: N vertically stacked piezoelectric stacks (N is the integer of 2 or above); wherein the each piezoelectric stack comprises: a piezoelectric sheet; a top electrode pattern on a top of the piezoelectric sheet; and a bottom electrode pattern on a bottom of the piezoelectric sheet, wherein each of the top and bottom electrode patterns has first and second sub-electrode patterns, wherein the first and second sub-electrode patterns are electrically insulated from each other, wherein the first and second sub-electrode patterns are horizontally interdigitated with each other, wherein the first sub-electrode patterns of the top and bottom electrode patterns vertically overlap with each other, wherein the second sub-electrode patterns of the top and bottom electrode patterns vertically overlap with each other, wherein the bottom electrode of the Nth piezoelectric stack is the top electrode of the N-1th piezoelectric stack.

### CROSS-REFERENCE TO RELATED APPLICATION

This application claims the benefit of Korean patent application No. 10-2017-0027504 filed on Mar. 3, 2017, the entire content of which is incorporated herein by reference for all purposes as if fully set forth herein.

### BACKGROUND

### Field of the Present Disclosure

The present disclosure relates to a piezoelectric structure including an electrode pattern, and more particularly, to a structure for converting mechanical strain into electrical energy (and vice versa) using a piezoelectric material sheet structure or a laminated structure of piezoelectric material sheets.

### Discussion of Related Art

In recent years, there has been an increasing demand, there has been an increasing demand for slimmer and thinner electronic devices. Accordingly, miniaturization of the size and thickness of piezoelectric transducers such as a piezoelectric sensor, a piezoelectric actuator and a piezoelectric energy harvester. applied to a smart phone, a thin film display device, an acoustic film device, a portable computer, and the like is required.

Piezoelectric transducers may be used in various ways, including piezoelectric energy harvesters, piezoelectric actuators, and piezoelectric sensors.

Piezoelectric transducers can be generally used in two modes, the longitudinal vibration mode and the transversal vibration mode.

In the transversal vibration mode, the piezoelectric material is electrically polarized in a direction vertical to the piezoelectric material sheet. However, in the longitudinal vibration mode, the piezoelectric material sheet is electrically polarized along the longitudinal direction of the sheet. FIG. 1 shows schematics of the two piezoelectric transduction modes: (a) longitudinal mode (3-3) and (b) transverse mode (3-1). In the transverse mode, voltage occurs as stress acts in the thickness direction when electrodes are attached to both surfaces of a piezoelectric film, whereas the voltage appears as the stress acts in the longitudinal direction (in-plane) perpendicular to the thickness direction in the longitudinal mode.

To achieve the longitudinal vibration mode, an interdigitated electrode (IDE) pattern is applied onto the piezoelectric film. FIG. 2 shows schematic diagrams of simplified electric field distribution for three types of IDE piezoelectric film: (a) IDE only on a top surface, (b) IDE on top and bottom, and (c) laminate. In cases of (a) IDE only on a top surface and (b) IDE on top and bottom, the inactive areas including dead area (D) and transition area (T) are large, because IDE fingers cannot sufficiently contribute to the piezoelectric transduction along the longitudinal direction because the polarization direction in the inactive area is not parallel to the in-plane direction.

In this invention, the inventors want to provide the IDE piezoelectric films stacked vertically like (c) laminate to decrease the inactive area and to enhance piezoelectric effect along the in-plane direction by increasing effective electrode area of IDE embedment in the piezoelectric laminate.

### SUMMARY

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

The interdigitated electrode patterned multi-layered piezoelectric laminate structure according to the present invention comprising: N vertically stacked piezoelectric stacks (N is the integer of 2 or above, from bottom to top the number is increased by 1); wherein the each piezoelectric stack comprises: a piezoelectric sheet; a top electrode pattern on a top of the piezoelectric sheet; and a bottom electrode pattern on a bottom of the piezoelectric sheet, wherein each of the top and bottom electrode patterns has first and second sub-electrode patterns, wherein the first and second sub-electrode patterns are electrically insulated from each other, wherein the first and second sub-electrode patterns are horizontally interdigitated with each other, wherein the first sub-electrode patterns of the top and bottom electrode patterns vertically overlap with each other, wherein the second sub-electrode patterns of the top and bottom electrode patterns vertically overlap with each other, wherein the bottom electrode of the Nth piezoelectric stack is the top electrode of the N-1th piezoelectric stack.

In one implementation of the first aspect, the piezoelectric laminate structure further comprises a substrate, when the substrate is disposed on the top or bottom pattern, a further piezoelectric sheet (dummy sheet) is formed between the top or bottom pattern and the substrate in order to prevent direct contact between the substrate and the top or bottom electrode pattern. The substrate is made of metal, ceramic, magneto-strictive material, magneto-electric material or piezo-magnetic material.

In one implementation of the first aspect, the piezoelectric multi-stack is formed into a unitary structure.

In one implementation of the first aspect, the unitary structure is formed via sintering of N vertically stacked piezoelectric stacks (especially ceramics).

In one implementation of the first aspect, each of the top and bottom first sub-electrode patterns has a longitudinal portion extending in a longitudinal direction, and a plurality of transverse branches extending from the longitudinal portion in a transverse direction and spaced apart from one another in the longitudinal direction, wherein each of top and bottom second sub-electrode patterns has a longitudinal portion extending in a longitudinal direction, and a plurality of transverse branches extending from the longitudinal portion in a transverse direction and spaced apart from one another in the longitudinal direction, wherein the longitudinal portions of the top and bottom first sub-electrode patterns are parallel with the longitudinal portions of the top and bottom second sub-electrode patterns respectively, wherein the plurality of transverse branches of the top first sub-electrode pattern are interdigitated with the plurality of transverse branches of the top second sub-electrode pattern, wherein the plurality of transverse branches of the bottom first sub-electrode pattern are interdigitated with the plurality of transverse branches of the bottom second sub-electrode pattern.

The piezoelectric transducer according to the present invention comprising the interdigitated electrode patterned multi-layered piezoelectric laminate structure comprising: N vertically stacked piezoelectric stacks (N is the integer of 2 or above); wherein the each piezoelectric stack comprises: a piezoelectric sheet; a top electrode pattern on a top of the piezoelectric sheet; and a bottom electrode pattern on a bottom of the piezoelectric sheet, wherein each of the top and bottom electrode patterns has first and second sub-electrode patterns, wherein the first and second sub-electrode patterns are electrically insulated from each other, wherein the first and second sub-electrode patterns are horizontally interdigitated with each other, wherein the first sub-electrode patterns of the top and bottom electrode patterns vertically overlap with each other, wherein the second sub-electrode patterns of the top and bottom electrode patterns vertically overlap with each other, wherein the bottom electrode of the Nth piezoelectric stack is the top electrode of the N-1th piezoelectric stack.

In one implementation of the second aspect, the piezoelectric laminate structure further comprises a substrate, when the substrate is disposed on the top or bottom pattern, a further piezoelectric sheet (dummy sheet) is formed between the top or bottom pattern and the substrate in order to prevent direct contact between the substrate and the top or bottom electrode pattern. The substrate is made of metal, ceramic, magneto-strictive material, magneto-electric material or piezo-magnetic material.

In one implementation of the second aspect, the piezoelectric multi-stack is formed into a unitary structure.

In one implementation of the second aspect, the unitary structure is formed via sintering of N vertically stacked piezoelectric stacks (especially ceramics).

In one implementation of the second aspect, each of the top and bottom first sub-electrode patterns has a longitudinal portion extending in a longitudinal direction, and a plurality of transverse branches extending from the longitudinal portion in a transverse direction and spaced apart from one another in the longitudinal direction, wherein each of top and bottom second sub-electrode patterns has a longitudinal portion extending in a longitudinal direction, and a plurality of transverse branches extending from the longitudinal portion in a transverse direction and spaced apart from one another in the longitudinal direction, wherein the longitudinal portions of the top and bottom first sub-electrode patterns are parallel with the longitudinal portions of the top and bottom second sub-electrode patterns respectively, wherein the plurality of transverse branches of the top first sub-electrode pattern are interdigitated with the plurality of transverse branches of the top second sub-electrode pattern, wherein the plurality of transverse branches of the bottom first sub-electrode pattern are interdigitated with the plurality of transverse branches of the bottom second sub-electrode pattern.

The piezoelectric structure including the electrode pattern according to the present invention realizes more efficient piezoelectric transduction by using the structure in which the piezoelectric bodies are laminated. At the same time, by embedding the IDE electrode pattern in the laminated structure, the poling effect is maximized to improve the piezoelectric effect along the in-plane direction.

### BRIEF DESCRIPTION OF THE DRAWINGS

The accompanying drawings, which are incorporated in and form a part of this specification and in which like numerals depict like elements, illustrate embodiments of the present disclosure and, together with the description, serve to explain the principles of the disclosure.

FIG. 1 shows schematics of the piezoelectric transduction modes: (a) longitudinal mode (3-3) and (b) transverse mode (3-1).

FIG. 2 shows schematic diagrams of simplified electric field distribution for three types of IDE piezoelectric film.

FIG. 3 is a perspective view for illustrating a piezoelectric material sheet structure according to an embodiment of the present invention.

FIG. 4 to FIG. 5 shows longitudinal sectional views of the embodiment of FIG. 3.

FIG. 6a shows an embodiment in which a further piezoelectric material sheet is formed.

FIG. 6b shows an embodiment in which a further piezoelectric material sheet is formed between the electrode and the substrate.

FIG. 7 is a perspective view for illustrating a piezoelectric material sheet structure according to a further embodiment of the present invention.

FIG. 8 and FIG. 9 show cross-sectional views taken along line I-I′ of FIG. 7.

FIGS. 10 and 11 are comparative diagrams for comparing an implementation using a piezoelectric material sheet structure according to an embodiment of the present invention and an implementation using a piezoelectric material sheet structure according to the prior art.

FIG. 12 is a schematic view of fabrication process for IDE piezoelectric structure according to the one embodiment of the present invention.

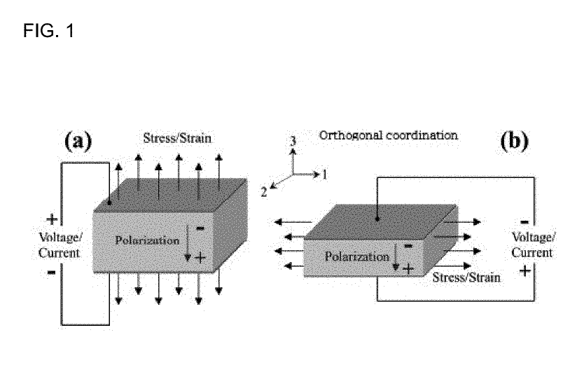

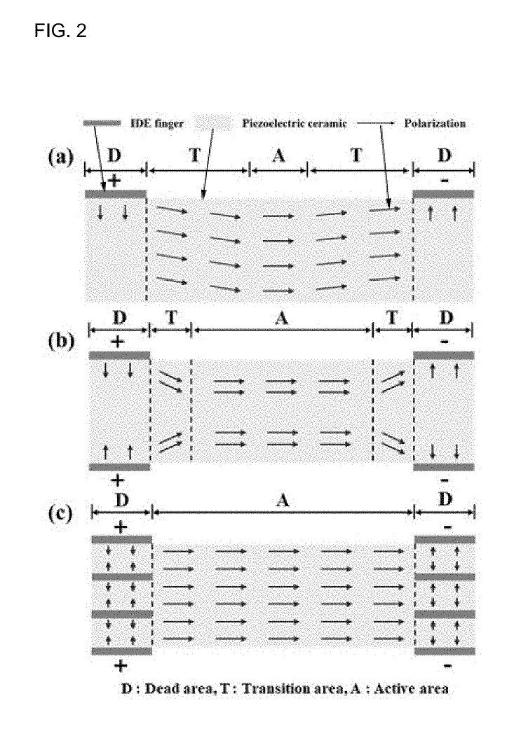

For simplicity and clarity of illustration, elements in the figures are not necessarily drawn to scale. The same reference numbers in different figures denote the same or similar elements, and as such perform similar functionality. Also, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

### DETAILED DESCRIPTIONS

Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “connected to”, or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

Spatially relative terms, such as “beneath,” “below,” “lower,” “under,” “above,” “upper,” and the like, may be used herein for ease of explanation to describe one element or feature's relationship to another element s or feature s as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented for example, rotated 90 degrees or at other orientations, and the spatially relative descriptors used herein should be interpreted accordingly.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the piezoelectric structure including the electrode pattern according to the embodiment of the present invention, the piezoelectric material sheet structure can be disposed on the substrate. The substrate is made of metal, ceramic, magneto-strictive material, magneto-electric material or piezo-magnetic material. The substrate may be an elastic substrate, a substrate, or the like, and is not particularly limited.

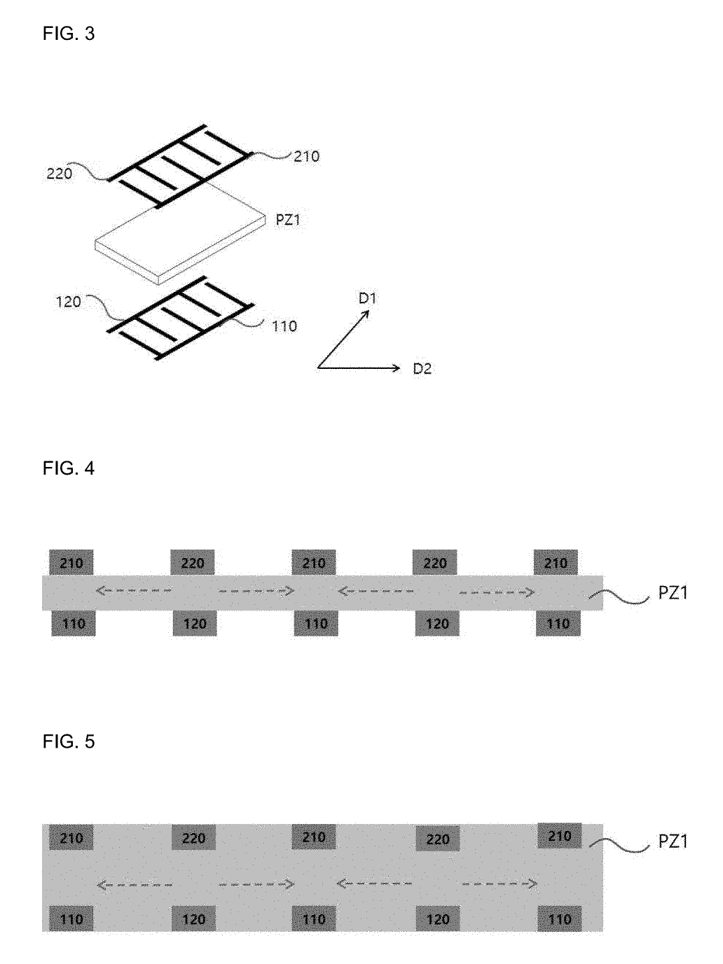

FIG. 3 is a perspective view for illustrating a piezoelectric stack according to one embodiment of the present invention.

The piezoelectric stack according to one embodiment of the present invention may include an first piezoelectric sheet PZ1; a top electrode pattern 210 and 220 on a top of the first piezoelectric sheet; and a bottom electrode pattern 110 and 120 on a bottom of the first piezoelectric sheet, wherein the top electrode pattern has first and second top sub-electrode patterns 210 and 220, wherein the first and second top sub-electrode patterns are electrically insulated from each other, wherein the first and second top sub-electrode patterns are horizontally interdigitated with each other, wherein the bottom electrode pattern 110 and 120 has first and second bottom sub-electrode patterns 110 and 120, wherein the first and second bottom sub-electrode patterns are electrically insulated from each other, wherein the first and second bottom sub-electrode patterns are horizontally interdigitated with each other, wherein the first top and bottom sub-electrode patterns vertically overlap with each other, wherein the second top and bottom sub-electrode patterns vertically overlap with each other, wherein the first piezoelectric sheet has a first polarization direction in a first piezoelectric-active region thereof.

The first piezoelectric sheet PZ1 is made of a piezoelectric material. Examples of the piezoelectric material may include piezoelectric ceramics, ceramic/polymer composites, and the like. The present invention is not limited to these.

Each of the top, and bottom first sub-electrode patterns may be interdigitated with each of the top, and bottom second sub-electrode patterns in a transverse direction perpendicular to a longitudinal direction thereof. In this connection, each longitudinal spacing between each of the top, and bottom first sub-electrode patterns 110, and 210 and each of the top, and bottom second sub-electrode patterns 120, 220 may define each piezoelectric-active region of the first piezoelectric sheets PZ1.

Each of the top and bottom first sub-electrode patterns 110, 210 has a longitudinal portion extending in a longitudinal direction D1, and a plurality of transverse branches extending from the longitudinal portion in a transverse direction D2 and spaced apart from one another in the longitudinal direction. Likewise, each of top, and bottom second sub-electrode patterns 120, 220 has a longitudinal portion extending in a longitudinal direction D1, and a plurality of transverse branches extending from the longitudinal portion in a transverse direction D2 and spaced apart from one another in the longitudinal direction. The longitudinal portion of each of the top, and bottom first sub-electrode patterns 110, 210 may be parallel with each of top, and bottom second sub-electrode patterns 120, 220. The plurality of transverse branches of each of the top, and bottom first sub-electrode patterns 110, 210 may be interdigitated with the plurality of transverse branches of each of top, and bottom second sub-electrode patterns 120, 220.

Each of the top, and bottom first sub-electrode patterns 110, 210, and each of the top, and bottom second sub-electrode patterns 120, 220 may be formed on the first piezoelectric sheet PZ1 by metal deposition and subsequent etching, or may be formed by direct laser plating, screen printing, inkjet printing or sputtering.

FIGS. 4 to 5 are sectional views taken along a line in FIG. 3.

In FIG. 4 and FIG. 5, the polarization directions are indicated by a dashed arrow. In one embodiment, in a first region, a first piezoelectric-active region of the first piezoelectric sheet PZ1, as defined between adjacent interdigitated transverse branches, the first piezoelectric sheet PZ1 has a first polarization direction. Likewise, in a second region adjacent to the first region, a second piezoelectric-active region of the first piezoelectric sheet PZ1, as defined between adjacent interdigitated transverse branches, the first piezoelectric sheet PZ1 has a second polarization direction opposite to the first polarization direction.

Although FIG. 4 shows that there is a space between adjacent electrodes, this is illustrated for convenience of illustration. Actually, as shown in FIG. 5, it is shown that there is filled a material of the PZ1 between the adjacent electrodes.

It should be noted that there is filled a material of the PZ1 between the top adjacent electrodes 210 and 220. Additionally or alternatively, it should be noted that there is filled a material of the PZ1 between the bottom adjacent electrodes 110 and 120 as shown in FIG. 5.

In accordance with the present disclosure, when the substrate 10 is formed on the top electrode pattern 210 and 220, a further piezoelectric sheet is formed between the first piezoelectric sheet PZ1 and the top electrode pattern 210 and 220 and the substrate, in order to prevent direct contact between the top electrode pattern 210 and 220 and the substrate 10. Additionally or alternatively, when the substrate 10 is formed on the bottom electrode pattern 110 and 120, a further piezoelectric sheet is formed between the first piezoelectric sheet PZ1 and the bottom electrode pattern 110 and 120 and the substrate, in order to prevent direct contact between the bottom electrode pattern 110 and 120 and the substrate 10.

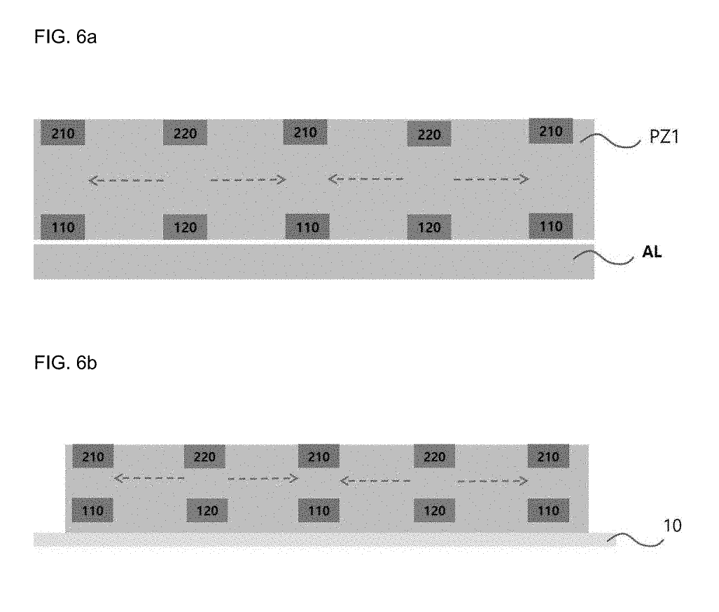

In one example in accordance with the present disclosure, when the substrate 10 is formed on the bottom electrode pattern 110 and 120, a further piezoelectric sheet AL is formed between the first piezoelectric sheet PZ1 and the bottom electrode pattern 110 and 120 and the substrate, in order to prevent direct contact between the bottom electrode pattern 110 and 120 and the substrate 10. This is shown in FIG. 6a. Additionally or alternatively, when the substrate 10 is formed on the top electrode pattern 210 and 220, a further piezoelectric sheet AL is formed between the first piezoelectric sheet PZ1 and the top electrode pattern 210 and 220 and the substrate, in order to prevent direct contact between the top electrode pattern 210 and 220 and the substrate 10.

In the case where the electrodes are directly in contact with the substrate, when the substrate is subjected to the strain and is deformed, the strain is not directly transferred to the piezoelectric sheet, but is transferred to the electrodes. Thus, the entire of the strain is not transmitted to the sheet, and only a portion of the strain reaches the piezoelectric material sheet. As a result, there is a problem that the action of the strain on the piezoelectric material sheet is not maximized. In order to solve this problem, as described above, the present invention includes an additional piezoelectric material sheet layer (AL) disposed between the substrate and the electrodes, whereby when strain of the substrate occurs, the strain can be directly transferred to the piezoelectric material sheet. As a result, the action of the strain on the piezoelectric material sheet is maximized, and, thus, the poling or polarization effect is maximized.

This is shown in FIG. 6b in a schematically. That is, as shown in FIG. 6b, when the substrate 10 is formed on the bottom electrode pattern 110 and 120, the further piezoelectric sheet is formed between the first piezoelectric sheet and the bottom electrode pattern no and 120 and the substrate 10, in order to prevent direct contact between the bottom electrode pattern no and 120 and the substrate 10. Additionally or alternatively, although not shown, when the substrate 10 is formed on the top electrode pattern 210 and 220, the further piezoelectric sheet is formed between the first piezoelectric sheet and the top electrode pattern 210 and 220 and the substrate, in order to prevent direct contact between the top electrode pattern 210 and 220 and the substrate 10. By embedding the electrode pattern in the structure, the electrode area is wider, the capacitance is higher and the impedance is lower, thus the piezoelectric conversion performance is improved.

Although, in the drawings, that is, in FIG. 4, it is shown that a space is defined between the bottom and top adjacent electrodes. However, actually, the present stack is actually formed via sintering so that the space is not present.

Meanwhile, as we mentioned in the discussion of the related art, to decrease the inactive area (dead area+transition area) and to make the transducer thinner the IDE piezoelectric films stacked vertically like laminate.

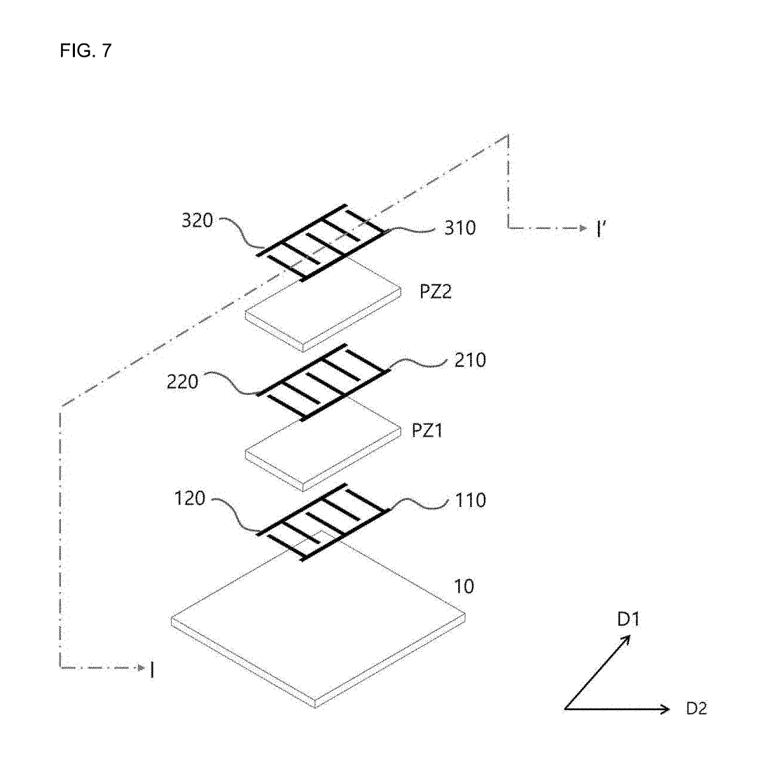

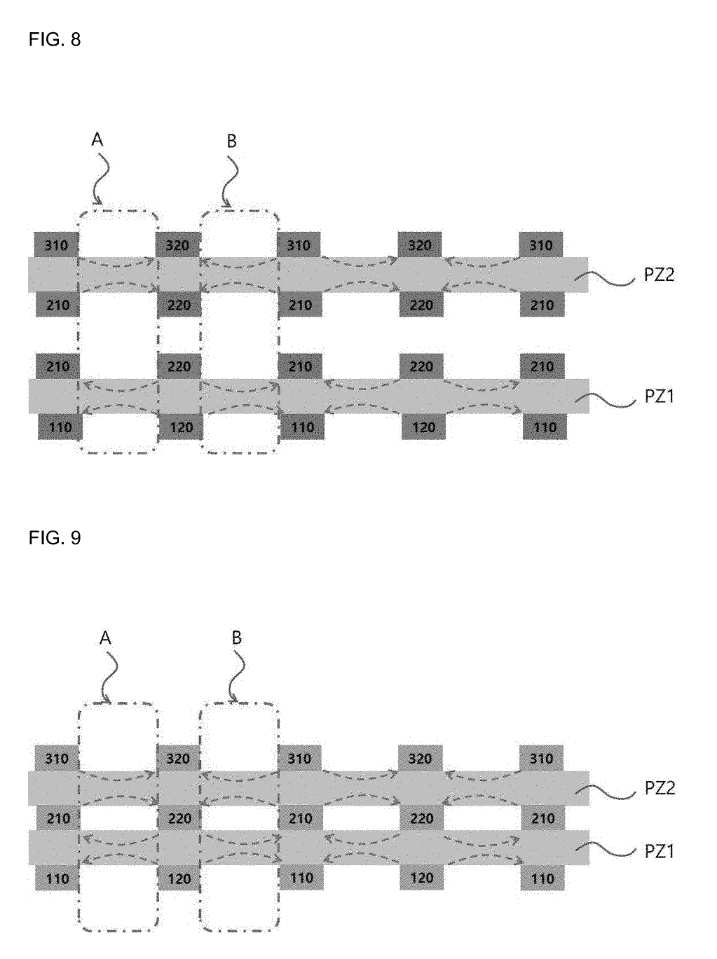

FIG. 7 is a perspective view for illustrating a piezoelectric material sheet structure according to a further embodiment of the present invention. FIG. 8 and FIG. 9 show cross-sectional views taken along line I-I′ of FIG. 7.

Referring to FIG. 7, FIG. 8 and FIG. 9, the piezoelectric stack according to this embodiment of the present invention may include an upper piezoelectric sheet; a top electrode pattern on a top of the upper piezoelectric sheet; a middle electrode pattern on a bottom of the upper piezoelectric sheet; a lower piezoelectric sheet on a bottom of the middle electrode pattern; and a bottom electrode pattern on a bottom of the lower piezoelectric sheet, wherein the top electrode pattern has first and second top sub-electrode patterns, wherein the first and second top sub-electrode patterns are electrically insulated from each other, wherein the first and second top sub-electrode patterns are horizontally interdigitated with each other, wherein the middle electrode pattern has first and second middle sub-electrode patterns, wherein the first and second middle sub-electrode patterns are electrically insulated from each other, wherein the first and second middle sub-electrode patterns are horizontally interdigitated with each other, wherein the bottom electrode pattern has first and second bottom sub-electrode patterns, wherein the first and second bottom sub-electrode patterns are electrically insulated from each other, wherein the first and second bottom sub-electrode patterns are horizontally interdigitated with each other, wherein the first top, middle and bottom sub-electrode patterns vertically overlap with each other, wherein the second top, middle and bottom sub-electrode patterns vertically overlap with each other, wherein the upper piezoelectric sheet has a first polarization direction in a first piezoelectric-active region thereof, and the lower piezoelectric sheet has a second polarization direction in a second piezoelectric-active region thereof, wherein the first polarization direction is same as the second polarization direction, wherein the first piezoelectric-active region vertically overlaps the second piezoelectric-active region.

Referring to FIG. 7, the piezoelectric stack according to one embodiment of the present invention includes upper and lower piezoelectric sheets PZ1 and PZ2, and top, middle and bottom electrode patterns 110, 120, 210, 220, 310, and 320.

Each of the upper and lower piezoelectric sheets PZ1 and PZ2 is made of a piezoelectric material. Examples of the piezoelectric material may include piezoelectric ceramics, ceramic/polymer composites, and the like. The present invention is not limited to this.

Each of the top, middle and bottom electrode patterns 110, 120, 210, 220, 310, and 320 may has each pair of each of top, middle and bottom first sub-electrode patterns 110, 210, and 310, and each of top, middle and bottom second sub-electrode patterns 120, 220 and 320. Each of the top, middle and bottom first sub-electrode patterns may be electrically insulated from each of the top, middle and bottom second sub-electrode patterns. Each of the top, middle and bottom first sub-electrode patterns may be horizontally interdigitated with each of the top, middle and bottom second sub-electrode patterns.

Each of the top, middle and bottom first sub-electrode patterns 110, 210, and 310 may be interdigitated with each of the top, middle and bottom second sub-electrode patterns 120, 220 and 320 in a transverse direction perpendicular to a longitudinal direction thereof. In this connection, each longitudinal spacing between each of the top, middle and bottom first sub-electrode patterns 110, 210, and 310 and each of the top, middle and bottom second sub-electrode patterns 120, 220 and 320 may define each piezoelectric-active region of each of the lower and upper piezoelectric sheets PZ1 and PZ2. A polarization direction in each piezoelectric-active region will be described later with reference to FIG. 8 and FIG. 9.

Each of the top, middle and bottom first sub-electrode patterns 110, 210, and 310 has a longitudinal portion extending in a longitudinal direction D1, and a plurality of transverse branches extending from the longitudinal portion in a transverse direction D2 and spaced apart from one another in the longitudinal direction. Likewise, each of top, middle and bottom second sub-electrode patterns 120, 220 and 320 has a longitudinal portion extending in a longitudinal direction D1, and a plurality of transverse branches extending from the longitudinal portion in a transverse direction D2 and spaced apart from one another in the longitudinal direction. The longitudinal portion of each of the top, middle and bottom first sub-electrode patterns 110, 210, and 310 may be parallel with each of top, middle and bottom second sub-electrode patterns 120, 220 and 320. The plurality of transverse branches of each of the top, middle and bottom first sub-electrode patterns 110, 210, and 310 may be interdigitated with the plurality of transverse branches of each of top, middle and bottom second sub-electrode patterns 120, 220 and 320.

The lower piezoelectric sheet PZ1 may be interposed between a pair of the bottom first and second sub-electrode patterns 110 and 120 and a pair of the middle first and second sub-electrode patterns 210 and 220. The upper piezoelectric sheet PZ2 may be interposed between a pair of the middle first and second sub-electrode patterns 210 and 220 and a pair of the top first and second sub-electrode patterns 310 and 320.

Each of the top, middle and bottom first sub-electrode patterns 110, 210, and 310 and each of the top, middle and bottom second sub-electrode patterns 120, 220 and 320 may be formed on the lower and upper piezoelectric sheets PZ1 and PZ2 by metal deposition and subsequent etching, or may be formed on the lower and upper piezoelectric sheets PZ1 and PZ2 by direct laser plating, screen printing, inkjet printing or sputtering.

Although, in the drawings, it is shown that a space is defined between the piezoelectric sheets PZ1 and PZ2, the piezoelectric sheets PZ1 and PZ2 are actually united via sintering so that the space is not present. In addition, although the middle electrode pattern is shown as being vertically divided into two portions in FIG. 8, this is only for convenience in illustrating the piezoelectric stack. These may be equally applied to all figures herein.

FIGS. 8 to 9 are sectional views taken along a line I-I′ in FIG. 7.

Referring to FIG. 7 together with FIGS. 8 and 9, a polarization direction in a piezoelectric-active region of the lower piezoelectric sheet PZ1 is same as a polarization direction in the same piezoelectric-active region of the upper piezoelectric sheet PZ2.

Although the middle electrode pattern 210 and 220 is shown as being vertically divided into two portions in FIG. 8, actually, as in FIG. 9, the middle electrode pattern 210 and 220 is not vertically divided.

In FIG. 8 and FIG. 9, the polarization directions are indicated by a dashed arrow.

Meanwhile, the piezoelectric stack according to the present invention may be formed into a unitary structure by forming a stack of the upper and lower piezoelectric sheets and upper, middle and lower electrode patterns and then sintering an entirety of the stack. That is, the unitary structure may formed by forming the interdigitated electrode patterns on the thin film-type piezoelectric sheets individually, stacking the piezoelectric sheets to form a stack, and sintering and firing an entirety of the stack. Particularly, in terms of material crystallinity, the unitary structure formed via this sintering is different from a mere combination between the upper and lower piezoelectric sheets and upper, middle and lower electrode patterns.

The piezoelectric stack according to the present invention as described above may be applied to a piezoelectric speaker device, a piezoelectric energy harvester, or a piezoelectric actuator.

In accordance with the present disclosure, when the substrate 10 is formed on the top electrode pattern 310 and 320, a further piezoelectric sheet is formed between the piezoelectric sheet PZ2 and the top electrode pattern 310 and 320 and the substrate 10, in order to prevent direct contact between the top electrode pattern 310 and 320 and the substrate 10. Additionally or alternatively, when the substrate 10 is formed on the bottom electrode pattern 110 and 120, a further piezoelectric sheet is formed between the lower piezoelectric sheet PZ2 and the bottom electrode pattern 110 and 120 and the substrate, in order to prevent direct contact between the bottom electrode pattern 110 and 120 and the substrate 10.

It should be noted that there is filled a material of the PZ2 between the top adjacent electrodes 310 and 320. Additionally or alternatively, it should be noted that there is filled a material of the PZ1 between the bottom adjacent electrodes 110 and 120 as in FIG. 3.

Otherwise, in the case where the electrodes are directly in contact with the substrate, when the substrate is subjected to the strain and is deformed, the strain is not directly transferred to the piezoelectric sheet, but is transferred to the electrodes. Thus, the entire of the strain is not transmitted to the sheet, and only a portion of the strain reaches the piezoelectric material sheet. As a result, there is a problem that the action of the strain on the piezoelectric material sheet is not maximized. In order to solve this problem, as described above, the present invention includes an additional piezoelectric material sheet layer (not labeled) disposed between the substrate and the electrodes, whereby when strain of the substrate occurs, the strain can be directly transferred to the piezoelectric material sheet. As a result, the action of the strain on the piezoelectric material sheet is maximized, and, thus, the poling or polarization effect is maximized.

When the piezoelectric stack is applied to the piezoelectric energy harvester, lead wires are connected to the electrode patterns of the piezoelectric stack. When external forces are applied to this piezoelectric stack, mechanical energy is converted to electrical energy via deformation of the lower and upper piezoelectric sheets. In this way, energy is harvested via the lead wires. In this case, a rectifying diode may be disposed between the lead wire and an energy storage device.

Based on the embodiment of FIG. 7 to FIG. 9, the following generalization may be realized in accordance with the present disclosure, the further embodiment of the present invention comprises N vertically stacked piezoelectric stacks (N is the integer of 2 or above). In case of N vertically stacked piezoelectric stacks, the each piezoelectric stack comprises: a piezoelectric sheet; a top electrode pattern on a top of the piezoelectric sheet; and a bottom electrode pattern on a bottom of the piezoelectric sheet, wherein each of the top and bottom electrode patterns has first and second sub-electrode patterns, wherein the first and second sub-electrode patterns are electrically insulated from each other, wherein the first and second sub-electrode patterns are horizontally interdigitated with each other, wherein the first sub-electrode patterns of the top and bottom electrode patterns vertically overlap with each other, wherein the second sub-electrode patterns of the top and bottom electrode patterns vertically overlap with each other, wherein the bottom electrode of the Nth piezoelectric stack is the top electrode of the N-1th piezoelectric stack. The Nth piezoelectric stack shares the top electrode of the N-1th piezoelectric stack.

The piezoelectric multi-stack of the present invention may be formed via sintering of a stack of the N vertically stacked electrodes and N-1 vertically stacked piezoelectric material sheets, wherein each of the vertically stacked piezoelectric material sheets is interposed between each two vertically stacked electrodes, that is the N electrodes and the N-1 sheets are arranged vertically one after the other, alternatively. For example, the piezoelectric multi-stack of the present invention is as follows: 1^{st} electrode, 1^{st} piezoelectric material sheet, 2^{nd} electrode, 2^{nd} piezoelectric material sheet, . . . , n-1^{th} electrode, n-1^{th} piezoelectric material sheet, n^{th} electrode. In this way, the piezoelectric multi-stack is formed into a unitary structure. That is, the unitary structure may formed by forming the interdigitated electrode patterns on the thin film-type piezoelectric sheets individually, stacking the piezoelectric sheets to form a multi-stack, and sintering and firing an entirety of the multi-stack. Particularly, in terms of material crystallinity, the unitary structure formed via this sintering is different from a mere combination between the bottom electrode pattern, the lower stack, the N-1 lower electrode patterns, the middle electrode pattern, the upper stack, the N-1 upper electrode patterns, and the top electrode pattern.

In accordance with the present disclosure, in the embodiment of the piezoelectric multi-stack, when the substrate is disposed on the upper stack, the piezoelectric sheet is further formed between the topmost electrode patterns and the substrate in order to prevent direct contact between the substrate and the topmost electrode pattern. Alternatively, when the substrate is disposed on the lower stack, the piezoelectric sheet is further formed between the lowest patterns and the substrate in order to prevent direct contact between the substrate and the lowest patterns.

In one embodiment of the piezoelectric multi-stack, the piezoelectric multi-stack is formed via sintering of a stack of the bottom electrode pattern, the lower stack, the N-1 lower electrode patterns, the middle electrode pattern, the upper stack, the N-1 upper electrode patterns, and the top electrode pattern.

In accordance with the present disclosure, when the substrate 10 is formed on the topmost electrode pattern, a further piezoelectric sheet is formed between the topmost piezoelectric sheet and the topmost electrode pattern and the substrate 10, in order to prevent direct contact between the topmost electrode pattern and the substrate 10. Additionally or alternatively, when the substrate 10 is formed on the bottom electrode pattern, a further piezoelectric sheet is formed between the lowest piezoelectric sheet and the bottom electrode pattern and the substrate, in order to prevent direct contact between the bottom electrode pattern and the substrate 10.

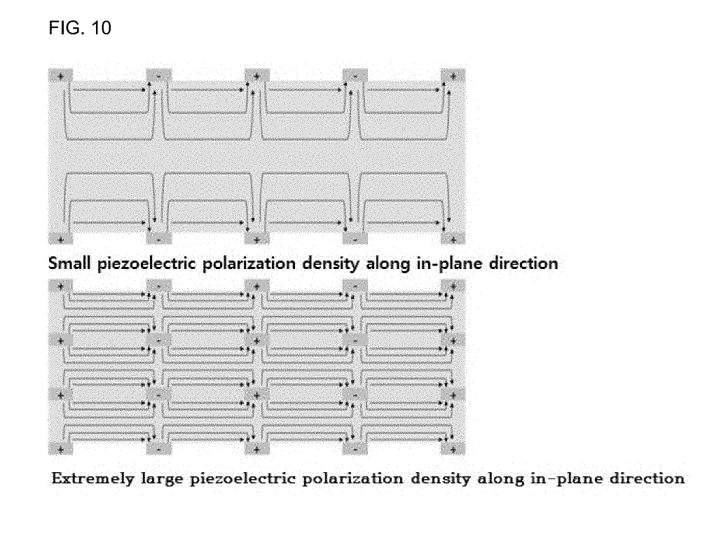

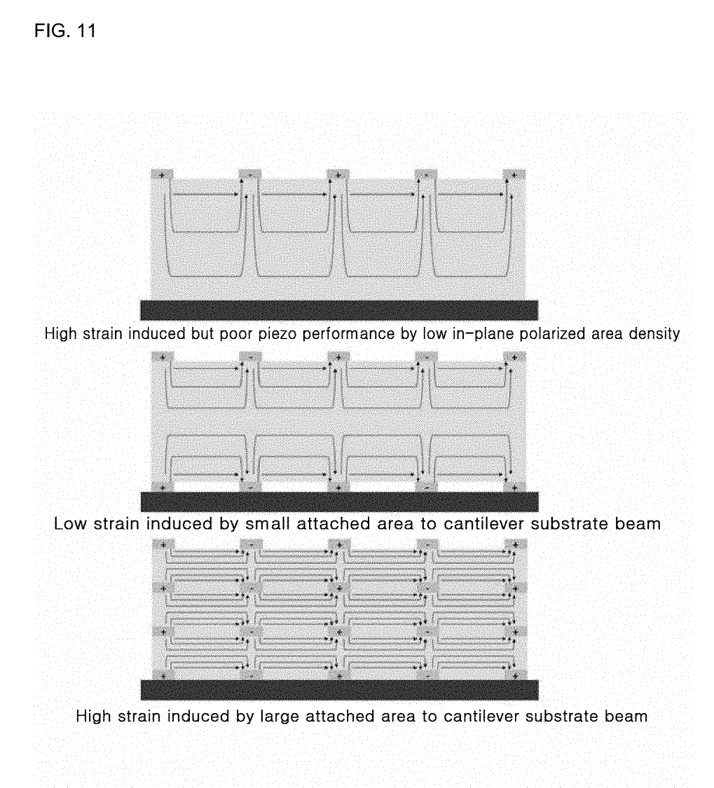

FIGS. 10 and 11 are comparative diagrams for comparing an implementation using a piezoelectric material sheet structure according to an embodiment of the present invention and an implementation using a piezoelectric material sheet structure according to the prior art.

As shown in the upper diagram of FIG. 10, the conventional IDE structure is formed not in the laminated type. But, in the upper diagram of FIG. 10, the IDE structure is formed on the upper and lower surfaces of the bulk piezoelectric ceramics. Since it is difficult to realize a thin thickness in manufacturing a piezoelectric material sheet structure including an IDE structure, the polarization density due to polarization formed in the longitudinal direction (3-3 mode) is very low even when the IDE pattern is used. Thus, it is difficult to realize various piezoelectric sensors, piezoelectric transducers, piezoelectric actuators and piezoelectric energy harvesters using the longitudinal mode (3-3 mode). For this reason, as shown in the prior art of the upper diagram of FIG. 10, it was common to use the 3-1 mode. However, in the present invention, as described above, the present piezoelectric laminated stack may be realized by lamination of a plurality of thin piezoelectric film sheet structures, each having an IDE pattern formed thereon, and sintering the laminate structures and co-firing the same.

Particularly, the piezoelectric stack according to the present invention may be formed into a unitary structure by forming a stack of the upper and lower piezoelectric sheets and upper, middle and lower electrode patterns and then sintering an entirety of the stack. That is, the unitary structure may formed by forming the interdigitated electrode patterns on the thin film-type piezoelectric sheets individually, stacking the piezoelectric sheets to form a stack, and sintering and firing an entirety of the stack. Particularly, in terms of material crystallinity, the unitary structure formed via this sintering is different from a mere combination between the upper and lower piezoelectric sheets and upper, middle and lower electrode patterns. As a result, when the piezoelectric material sheet stacked structure of the present invention is used, it is possible to maximize the polarization density in the 3-3 mode direction (see the lower diagram of FIG. 10, thereby realizing excellent performance in application to various piezoelectric materials.

Further, referring to FIG. 11, a piezoelectric film/elastomer film laminated structure similar to that of the cantilever structure will be described. When a piezoelectric film having an IDE pattern is attached to an elastic substrate, and as shown in the uppermost diagram in FIG. 11, and an IDE pattern is formed only on the upper surface of the piezoelectric sheet and the elastic substrate and the piezoelectric film are bonded directly to each other, a large strain is induced, but the piezoelectric performance is poor due to a low polarization density.

Further, in a middle diagram of FIG. 11, the IDEs are formed on both the upper surface and the lower surface of the piezoelectric sheet, and when the elastic substrate and the IDE electrode are directly bonded to each other, low strain induction occurs due to a small contact area between the piezoelectric sheet and the substrate, and, thus, the piezoelectric conversion performance is not good.

To the contrary, in a lower diagram of FIG. 11, the IDE patterns are formed on both the upper surface and the lower surface of the piezoelectric substrate, and the elastic substrate and the IDE are not in direct contact with each other, that is, each of the IDE pattern is embedded in the piezoelectric sheets. As a result, since the contact area between the piezoelectric sheets and the elastic substrate is larger and, thus, high polarization density is obtained, excellent piezoelectric conversion performance can be expected. By embedding the IDE pattern in the structure, the electrode area is widen, the capacitance is higher and the impedance is lower, thus the piezoelectric conversion performance is improved.

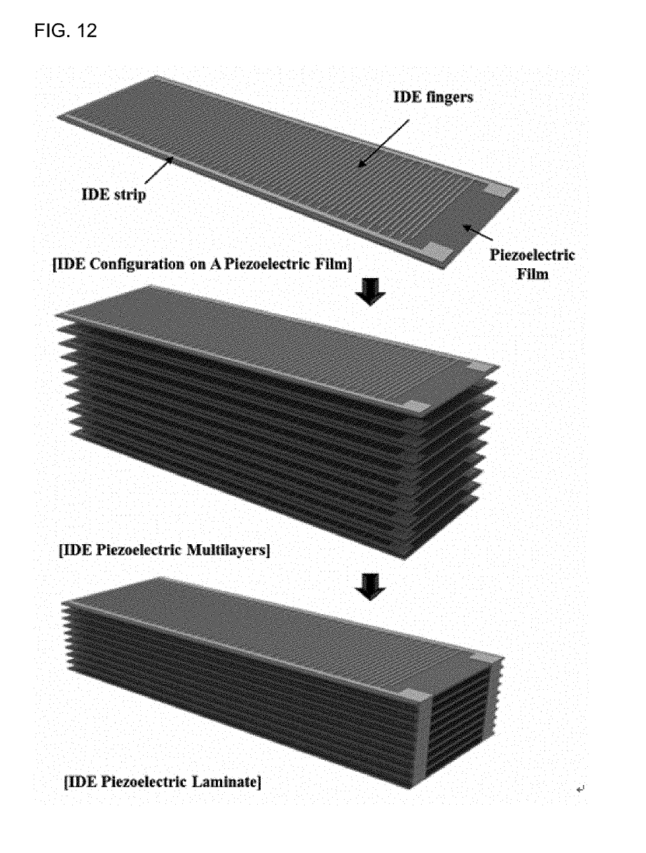

FIG. 12 is a view showing a process for manufacturing a piezoelectric laminated structure including an IDE pattern according to the present invention. As shown in FIG. 12, the IDE pattern may be disposed on the piezoelectric film, and the plurality of the piezoelectric films may be laminated on top of another. Then, the resulting stack may be sintered to form a unitary sintered body as the present piezoelectric stack.

The piezoelectric laminated structure according to the present invention described above may be used as a piezoelectric energy harvester by collecting output energy. The piezoelectric stack according to the present invention may also be used as a piezoelectric sensor as a sensing device that recognizes the output electrical energy as a voltage and changes the voltage.

The descriptions of the above-described embodiments are provided to enable any person skilled in the art to readily use or to practice the present invention. Various modifications to these embodiments will be readily apparent to those skilled in the art. Further, the generic principles defined herein may be applied to other embodiments without departing from the scope of the invention. Accordingly, the invention is not to be limited to the embodiments shown and described herein but is to be accorded the widest scope consistent with the principles and novel features presented herein.

What is claimed is:

1. An interdigitated electrode patterned multi-layered piezoelectric laminate structure, comprising:
N vertically stacked piezoelectric stacks (N is the integer of 2 or above, from bottom to top the number N is increased);
wherein the each piezoelectric stack comprises:
a piezoelectric sheet;
a top electrode pattern on a top of the piezoelectric sheet; and
a bottom electrode pattern on a bottom of the piezoelectric sheet,
wherein each of the top and bottom electrode patterns has first and second sub-electrode patterns, wherein the first and second sub-electrode patterns are electrically insulated from each other, wherein the first and second sub-electrode patterns are horizontally interdigitated with each other,
wherein the first sub-electrode patterns of the top and bottom electrode patterns vertically overlap with each other, wherein the second sub-electrode patterns of the top and bottom electrode patterns vertically overlap with each other,
wherein the bottom electrode of the Nth piezoelectric stack is the top electrode of the N-1th piezoelectric stack.

2. The piezoelectric laminate structure of claim 1, further comprising a substrate, wherein when the substrate is disposed on the top or bottom pattern, a further piezoelectric sheet is formed between the top or bottom pattern and the substrate in order to prevent direct contact between the substrate and the top or bottom electrode pattern.

3. The piezoelectric laminate structure of claim 2, the substrate is made of metal, ceramic, magneto-strictive material, magneto-electric material or piezo-magnetic material.

4. The piezoelectric laminate structure of claim 1, wherein the piezoelectric multi-stack is formed into a unitary structure.

5. The piezoelectric laminate structure of claim 4, wherein the unitary structure is formed via sintering of N vertically stacked piezoelectric stacks.

6. The piezoelectric laminate structure of claim 1, wherein each of the top and bottom first sub-electrode patterns has a longitudinal portion extending in a longitudinal direction, and a plurality of transverse branches extending from the longitudinal portion in a transverse direction and spaced apart from one another in the longitudinal direction,
wherein each of top and bottom second sub-electrode patterns has a longitudinal portion extending in a longitudinal direction, and a plurality of transverse branches extending from the longitudinal portion in a transverse direction and spaced apart from one another in the longitudinal direction,
wherein the longitudinal portions of the top and bottom first sub-electrode patterns are parallel with the longitudinal portions of the top and bottom second sub-electrode patterns respectively,
wherein the plurality of transverse branches of the top first sub-electrode pattern are interdigitated with the plurality of transverse branches of the top second sub-electrode pattern,
wherein the plurality of transverse branches of the bottom first sub-electrode pattern are interdigitated with the plurality of transverse branches of the bottom second sub-electrode pattern.

7. A piezoelectric transducer comprising an interdigitated electrode patterned multi-layered piezoelectric laminate structure, comprising:
N vertically stacked piezoelectric stacks (N is the integer of 2 or above);
wherein the each piezoelectric stack comprises:
a piezoelectric sheet;
a top electrode pattern on a top of the piezoelectric sheet; and
a bottom electrode pattern on a bottom of the piezoelectric sheet,
wherein each of the top and bottom electrode patterns has first and second sub-electrode patterns, wherein the first and second sub-electrode patterns are electrically insulated from each other, wherein the first and second sub-electrode patterns are horizontally interdigitated with each other,
wherein the first sub-electrode patterns of the top and bottom electrode patterns vertically overlap with each other, wherein the second sub-electrode patterns of the top and bottom electrode patterns vertically overlap with each other,
wherein the bottom electrode of the Nth piezoelectric stack is the top electrode of the N-1th piezoelectric stack.

8. The piezoelectric transducer of claim 7, further comprising a substrate, wherein when the substrate is disposed on the top or bottom pattern, a further piezoelectric sheet is formed between the top or bottom pattern and the substrate in order to prevent direct contact between the substrate and the top or bottom electrode pattern.

9. The piezoelectric transducer of claim 8, the substrate is made of metal, ceramic, magneto-strictive material, magneto-electric material or piezo-magnetic material.

10. The piezoelectric transducer of claim 7, wherein the piezoelectric multi-stack is formed into a unitary structure.

11. The piezoelectric transducer of claim 10, wherein the unitary structure is formed via sintering of N vertically stacked piezoelectric stacks.

12. The piezoelectric transducer of claim 7, wherein each of the top and bottom first sub-electrode patterns has a longitudinal portion extending in a longitudinal direction, and a plurality of transverse branches extending from the longitudinal portion in a transverse direction and spaced apart from one another in the longitudinal direction,
wherein each of top and bottom second sub-electrode patterns has a longitudinal portion extending in a longitudinal direction, and a plurality of transverse branches extending from the longitudinal portion in a transverse direction and spaced apart from one another in the longitudinal direction,
wherein the longitudinal portions of the top and bottom first sub-electrode patterns are parallel with the longitudinal portions of the top and bottom second sub-electrode patterns respectively,
wherein the plurality of transverse branches of the top first sub-electrode pattern are interdigitated with the plurality of transverse branches of the top second sub-electrode pattern,
wherein the plurality of transverse branches of the bottom first sub-electrode pattern are interdigitated with the plurality of transverse branches of the bottom second sub-electrode pattern.
